(19) United States
(12) Patent Application Publication
(10) Pub. No.: US 2025/0359283 A1
(43) Pub. Date: Nov. 20, 2025

(54) SEMICONDUCTOR DEVICE

(71) Applicant: Mitsubishi Electric Corporation, Tokyo (JP)

(72) Inventors: Hideo KOMO, Tokyo (JP); Ryoji MURAI, Fukuoka (JP)

(73) Assignee: Mitsubishi Electric Corporation, Tokyo (JP)

(21) Appl. No.: 18/854,808

(22) PCT Filed: Jul. 8, 2022
(86) PCT No.: PCT/JP2022/027063

§ 371 Date: Oct. 7, 2024

(51) Int. Cl. H10D 80/20; H01L 23/00; H01L 23/31; H01L 23/373; H01L 23/50; H01L 25/11

(52) U.S. Cl. CPC H10D 80/20; H01L 23/3121; H01L 23/3735; H01L 23/50; H01L 24/32; H01L 24/40; H01L 24/48; H01L 24/73; H01L 25/115; H01L 2224/32225; H01L 2224/40155; H01L 2224/48175; H01L 2224/73221; H01L 2224/73263; H01L 2224/73265; H01L 2924/10272; H01L 2924/13055; H01L 2924/30107

(57) ABSTRACT

A first terminal is provided on a first surface of the first semiconductor package and electrically connected to a first pole side of the first semiconductor chip. A first output terminal is provided on a second surface of the first semiconductor package and electrically connected to a second pole side of the first semiconductor chip. A second output terminal is provided on a third surface of the second semiconductor package and electrically connected to the first pole side of the second semiconductor chip. A second terminal is provided on the third surface of the second semiconductor package and electrically connected to the second pole side of the second semiconductor chip. The first output terminal is connected to the second output terminal. A bus bar is connected to the second terminal and extends from the second terminal in a direction of the first surface on which the first terminal is provided.

### TECHNICAL FIELD

The present disclosure relates to a semiconductor device.

### BACKGROUND ART

A structure in which two semiconductor devices are connected in series to each other is applied to various control systems such as power control apparatuses. In a semiconductor assembly described in Patent Document 1, two semiconductor devices having a common design are connected in series to each other. In each semiconductor device, a positive polarity terminal is provided on one side surface, and a negative polarity terminal is provided on the other side surface. The negative polarity terminal of one of semiconductor assemblies connected in series is folded back at a side surface thereof, passes above the two semiconductor devices, and extends in a direction of the positive polarity terminal.

### PRIOR ART DOCUMENT

### Patent Document

Patent Document 1: U.S. Pat. No. 10,304,770

### SUMMARY

### Problem to be Solved by the Invention

In a structure in which a plurality of semiconductor packages each including a switching element is connected in series to each other, a path of a bus bar for guiding one terminal toward the other terminal becomes long, and inductance becomes large.

In order to solve the above problem, the present disclosure provides a semiconductor device that reduces inductance of a circuit in which a plurality of semiconductor packages is connected in series.

### Means to Solve the Problem

A semiconductor device according to the present disclosure includes a first semiconductor package, a first terminal, a first output terminal, a second semiconductor package, a second output terminal, a second terminal, and a bus bar. The first semiconductor package includes a first semiconductor chip. The first terminal is provided on a first surface of the first semiconductor package. The first terminal is electrically connected to a first pole side of the first semiconductor chip. The first output terminal is provided on a second surface of the first semiconductor package. The first output terminal is electrically connected to a second pole side of the first semiconductor chip. The second semiconductor package includes a second semiconductor chip. The second output terminal is provided on a third surface of the second semiconductor package. The second output terminal is electrically connected to the first pole side of the second semiconductor chip. The second terminal is provided on the third surface of the second semiconductor package. The second terminal is electrically connected to the second pole side of the second semiconductor chip. The bus bar is connected to the second terminal. The first output terminal is connected to the second output terminal. The bus bar extends from the second terminal in a direction of the first surface on which the first terminal is provided.

### Effects of the Invention

With the semiconductor device of the present disclosure, inductance of a circuit in which a plurality of semiconductor packages is connected in series is reduced.

The objects, features, aspects, and advantages of the present disclosure will be more apparent from the following detailed description and the accompanying drawings.

### BRIEF DESCRIPTION OF DRAWINGS

FIG. 1 is a circuit diagram illustrating an example of a configuration of a three-phase inverter.

FIG. 2 is a cross-sectional view illustrating a configuration of an upper arm semiconductor package of a semiconductor device according to a first embodiment.

FIG. 3 is a view illustrating an internal structure of the upper arm semiconductor package.

FIG. 4 is a view illustrating a configuration of the upper arm semiconductor package.

FIG. 5 is a view illustrating an internal structure of a lower arm semiconductor package.

FIG. 6 is a view illustrating a configuration of the lower arm semiconductor package.

FIG. 7 is a view illustrating a connection configuration between the upper arm semiconductor package and the lower arm semiconductor package.

FIG. 8 is a view illustrating a configuration of the semiconductor device according to the first embodiment.

FIG. 9 is a view illustrating a configuration of a semiconductor device according to a second embodiment.

FIG. 10 is a view illustrating a configuration of a semiconductor device according to a third embodiment.

FIG. 11 is a view illustrating a connection configuration between an upper arm semiconductor package and a lower arm semiconductor package.

FIG. 12 is a view illustrating a configuration of the upper arm semiconductor package.

FIG. 13 is a view illustrating a configuration of the lower arm semiconductor package.

FIG. 14 is a view illustrating an internal structure of the upper arm semiconductor package.

FIG. 15 is a view illustrating an internal structure of the lower arm semiconductor package.

FIG. 16 is a plan view illustrating the internal structure of the upper arm semiconductor package.

FIG. 17 is a plan view illustrating the internal structure of the lower arm semiconductor package.

FIG. 18 is a view illustrating a configuration of a semiconductor device according to a fourth embodiment.

FIG. 19 is a side view illustrating an example of a holding structure of a semiconductor chip according to a fifth embodiment.

FIG. 20 is a view illustrating an example of a configuration of an upper arm semiconductor package and a bus bar according to a sixth embodiment.

FIG. 21 is a view illustrating an example of the configuration of the upper arm semiconductor package and the bus bar.

FIG. 22 is a plan view illustrating an internal structure of an upper arm semiconductor package according to a seventh embodiment.

FIG. 23 is a plan view illustrating an internal structure of a lower arm semiconductor package.

FIG. 24 is a view illustrating a configuration of a semiconductor device according to an eighth embodiment.

FIG. 25 is a plan view illustrating an internal structure of an upper arm semiconductor package according to a ninth embodiment.

FIG. 26 is a plan view illustrating an internal structure of a lower arm semiconductor package.

### DESCRIPTION OF EMBODIMENTS

### First Embodiment

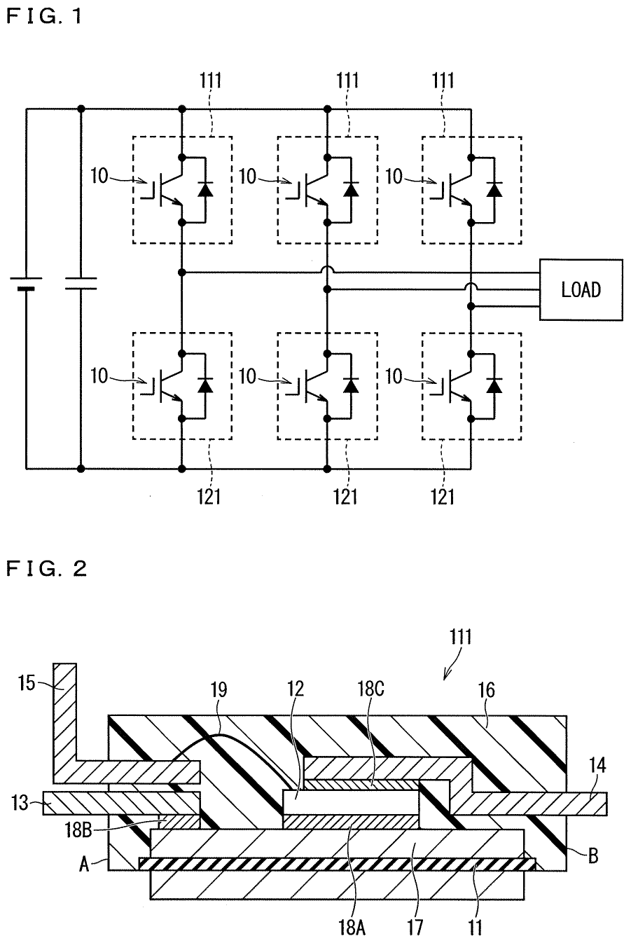

FIG. 1 is a circuit diagram illustrating an example of a configuration of a three-phase inverter. The three-phase inverter includes three upper arm semiconductor packages 111 and three lower arm semiconductor packages 121. Each of the upper arm semiconductor packages 111 and the lower arm semiconductor packages 121 includes a switching element 10. One upper arm semiconductor package 111 and one lower arm semiconductor package 121 are connected in series to form one leg.

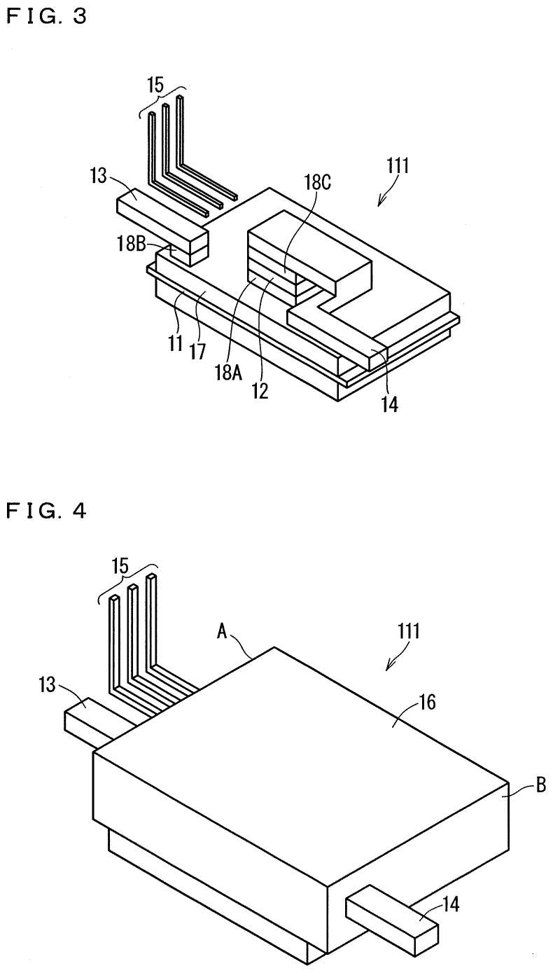

FIG. 2 is a cross-sectional view illustrating a configuration of the upper arm semiconductor package 111 of the semiconductor device according to the first embodiment. FIG. 3 is a view illustrating an internal structure of the upper arm semiconductor package 111. FIG. 4 is a view illustrating a configuration of the upper arm semiconductor package 111. However, in FIG. 2, the positional relationship in the height direction and the positional relationship in the depth direction of a P terminal 13, a first AC terminal 14, and a control terminal 15 are simplified, and are different from the original positional relationship in the first embodiment illustrated in FIG. 3.

The upper arm semiconductor package 111 includes an insulating substrate 11, a first semiconductor chip 12, a P terminal 13, a first AC terminal 14, a control terminal 15, and a sealing material 16.

The insulating substrate 11 includes a metal pattern 17 on its surface. The insulating substrate 11 holds the first semiconductor chip 12 on the metal pattern 17 via a bonding material 18A. The insulating substrate 11 is made of ceramic, for example.

The first semiconductor chip 12 includes a switching element 10. The first semiconductor chip 12 is formed of, for example, a semiconductor such as Si or a so-called wide bandgap semiconductor such as SiC, GaN, or gallium oxide. The first semiconductor chip 12 is a so-called power semiconductor chip. In the first semiconductor chip 12, an insulated gate bipolar transistor (IGBT) is formed as the switching element 10. The switching element 10 may be a reverse-conducting IGBT (RC-IGBT) in which an IGBT and a freewheeling diode are formed in one semiconductor substrate. Alternatively, the switching element 10 may be a metal oxide semiconductor field effect transistor (MOSFET) or the like.

The P terminal 13 is formed of, for example, a metal frame. The metal frame is formed of a metal flat plate or a sheet metal obtained by subjecting the metal flat plate to shape processing. One end of the P terminal 13 is connected to the metal pattern 17 by a bonding material 18B. That is, the P terminal 13 is electrically connected to a first pole side of the first semiconductor chip 12 via the metal pattern 17. The first pole side is a collector side of the IGBT. The other end of the P terminal 13 protrudes from a first side surface A of the upper arm semiconductor package 111. In other words, the P terminal 13 is provided on the first side surface A of the upper arm semiconductor package 111. The P terminal 13 is a positive electrode terminal.

The first AC terminal 14 is formed of, for example, a metal frame. One end of the first AC terminal 14 is connected to a surface electrode (not illustrated) of the first semiconductor chip 12 by a bonding material 18C. That is, the first AC terminal 14 is electrically connected to a second pole side of the first semiconductor chip 12. The surface electrode is an emitter electrode, and the second pole side is an emitter side of the IGBT. The other end of the first AC terminal 14 protrudes from a second side surface B of the upper arm semiconductor package 111. In other words, the first AC terminal 14 is provided on the second side surface B different from the first side surface A on which the P terminal 13 is provided. In the first embodiment, the sealing material 16 forming an outer shape of the upper arm semiconductor package 111 has a rectangular shape in plan view. The first side surface A and the second side surface B are surfaces opposite to each other in the rectangle. The first AC terminal 14 is a negative electrode terminal.

The control terminal 15 is a terminal for transmitting a control signal related to control of the switching element 10 included in the first semiconductor chip 12. The control terminal 15 is connected to the first semiconductor chip 12 via, for example, a control wire 19. Note that, in FIG. 3, illustration of the control wire 19 is omitted. A plurality of control terminals 15 may be provided. A part of the control terminal 15 protrudes from the first side surface A of the upper arm semiconductor package 111.

The sealing material 16 seals the metal pattern 17 of the insulating substrate 11, the first semiconductor chip 12, a part of the P terminal 13, a part of the first AC terminal 14, and a part of the control terminal 15. The sealing material 16 is, for example, a resin. The sealing material 16 is formed by, for example, molding. The sealing material 16 has a rectangular shape in plan view.

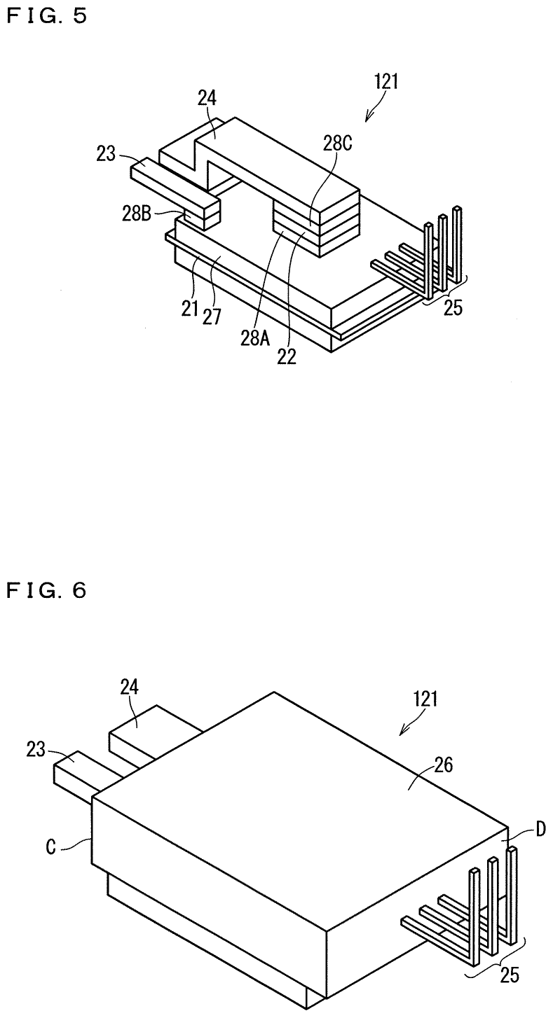

FIG. 5 is a view illustrating an internal structure of the lower arm semiconductor package 121. FIG. 6 is a view illustrating a configuration of the lower arm semiconductor package 121.

The lower arm semiconductor package 121 includes an insulating substrate 21, a second semiconductor chip 22, a second AC terminal 23, an N terminal 24, a control terminal 25, and a sealing material 26. Although a view illustrating a cross-sectional configuration of the lower arm semiconductor package 121 is omitted, the configurations of the insulating substrate 21, a metal pattern 27, and the sealing material 26 are similar to the configurations of the insulating substrate 11, the metal pattern 17, and the sealing material 16 of the upper arm semiconductor package 111, respectively.

The second semiconductor chip 22 includes a switching element 10. The configuration of the second semiconductor chip 22 is, for example, the same as the configuration of the first semiconductor chip 12. The second semiconductor chip 22 is held on the metal pattern 27 of the insulating substrate 21 via a bonding material 28A.

The second AC terminal 23 is formed of, for example, a metal frame. One end of the second AC terminal 23 is connected to the metal pattern 27 by a bonding material 28B. That is, the second AC terminal 23 is electrically connected to the first pole side of the second semiconductor chip 22 via the metal pattern 27. The first pole side is a collector side of the IGBT. The other end of the second AC terminal 23 protrudes from a third side surface C of the lower arm semiconductor package 121. In other words, the second AC terminal 23 is provided on the third side surface C of the lower arm semiconductor package 121. The second AC terminal 23 is a positive electrode terminal.

The N terminal 24 is formed of, for example, a metal frame. One end of the N terminal 24 is connected to a surface electrode (not illustrated) of the second semiconductor chip 22 by a bonding material 28C. That is, the N terminal 24 is electrically connected to the second pole side of the second semiconductor chip 22. The surface electrode is an emitter electrode, and the second pole side is an emitter side of the IGBT. The other end of the N terminal 24 protrudes from the third side surface C of the lower arm semiconductor package 121. The N terminal 24 is provided on the same surface as the third side surface C on which the second AC terminal 23 is provided. The N terminal 24 is a negative electrode terminal.

The control terminal 25 is a terminal for transmitting a control signal related to control of the switching element 10 included in the second semiconductor chip 22. The control terminal 25 is connected to the second semiconductor chip 22 via, for example, a control wire (not illustrated). A plurality of control terminals 25 may be provided. A part of the control terminal 25 protrudes from a fourth side surface D of the lower arm semiconductor package 121. In the first embodiment, the sealing material 26 forming an outer shape of the lower arm semiconductor package 121 has a rectangular shape in plan view. The third side surface C and the fourth side surface D are surfaces opposite to each other in the rectangle.

The sealing material 26 seals the metal pattern 27 of the insulating substrate 21, the second semiconductor chip 22, a part of the second AC terminal 23, a part of the N terminal 24, and a part of the control terminal 25. The sealing material 26 is, for example, a resin. The sealing material 26 is formed by, for example, molding. The sealing material 26 has a rectangular shape in plan view.

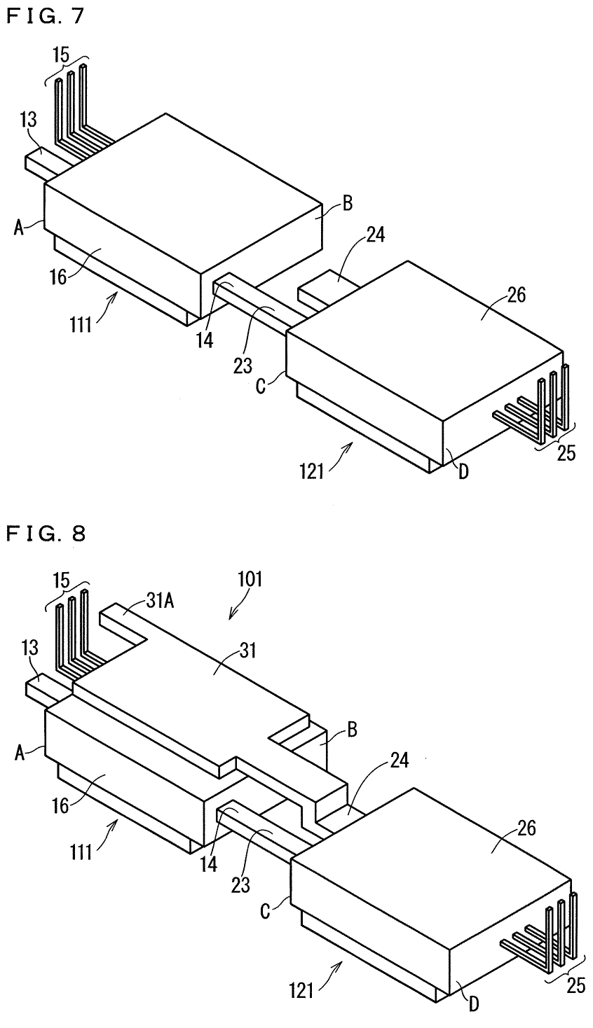

FIG. 7 is a view illustrating a connection configuration between the upper arm semiconductor package 111 and the lower arm semiconductor package 121. FIG. 8 is a view illustrating a configuration of the semiconductor device 101 according to the first embodiment.

The upper arm semiconductor package 111 is disposed so that the second side surface B thereof faces the third side surface C of the lower arm semiconductor package 121. The first AC terminal 14 is connected to the second AC terminal 23. Thus, the switching element 10 of the upper arm semiconductor package 111 and the switching element 10 of the lower arm semiconductor package 121 are connected in series with each other. When the semiconductor device 101 is incorporated in the inverter circuit, the AC wiring for supplying power to the load is connected to the first AC terminal 14 or the second AC terminal 23.

A bus bar 31 is connected to the N terminal 24 of the lower arm semiconductor package 121. The bus bar 31 extends from the N terminal 24 in the direction of the first side surface A on which the P terminal 13 is provided. The bus bar 31 in the first embodiment is disposed on an upper surface of the upper arm semiconductor package 111. In other words, the bus bar 31 extends in the direction of the first side surface A from the N terminal 24 across the upper surface of the upper arm semiconductor package 111.

The bus bar 31 includes a bus bar terminal portion 31A on the first side surface A side of the upper arm semiconductor package 111. The bus bar terminal portion 31A is disposed side by side with the P terminal 13 of the upper arm semiconductor package 111. The bus bar terminal portion 31A is at the same potential as the N terminal 24 of the lower arm semiconductor package 121.

To summarize the above, the semiconductor device 101 according to the first embodiment includes the upper arm semiconductor package 111, the P terminal 13, the first AC terminal 14, the lower arm semiconductor package 121, the second AC terminal 23, the N terminal 24, and the bus bar 31. The upper arm semiconductor package 111 includes the first semiconductor chip 12. The P terminal 13 is provided on the first side surface A as an example of the first surface of the upper arm semiconductor package 111. The P terminal 13 is electrically connected to the first pole side of the first semiconductor chip 12. The first AC terminal 14 is provided on the second side surface B as an example of the second surface of the upper arm semiconductor package 111. The first AC terminal 14 is electrically connected to the second pole side of the first semiconductor chip 12. The lower arm semiconductor package 121 includes the second semiconductor chip 22. The second AC terminal 23 is provided on the third side surface C as an example of the third surface of the lower arm semiconductor package 121. The second AC terminal 23 is electrically connected to the first pole side of the second semiconductor chip 22. The N terminal 24 is provided on the third side surface C as an example of the third surface of the lower arm semiconductor package 121. The N terminal 24 is electrically connected to the second pole side of the second semiconductor chip 22. The bus bar 31 is connected to the N terminal 24. The first AC terminal 14 is connected to the second AC terminal 23. The bus bar 31 extends from the N terminal 24 in the direction of the first side surface A as an example of the first surface on which the P terminal 13 is provided.

When the switching elements 10 included in the first semiconductor chip 12 and the second semiconductor chip 22 are IGBTs, the first pole side is the collector side of the IGBT, and the second pole side is the emitter side. When the switching element 10 is a MOSFET, the first pole side is the drain side of the MOSFET, and the second pole side is the source side.

Such a semiconductor device 101 reduces inductance in a circuit in which the upper arm semiconductor package 111 and the lower arm semiconductor package 121 are connected in series.

In the first embodiment, an example in which the semiconductor device 101 is applied to a three-phase inverter has been described. However, the device in which the semiconductor device 101 is incorporated is not limited to the three-phase inverter. The semiconductor device 101 can be applied to a system in which a plurality of semiconductor packages is connected in series, such as other power control apparatuses and signal processing devices, and such a system has effects similar to those described above. Further, the first pole side may be the negative electrode side, and the second pole side may be the positive electrode side.

### Second Embodiment

The second embodiment is a subordinate concept of the first embodiment. In the second embodiment, components similar to those in the first embodiment are denoted by the same reference numerals, and the detailed description thereof will be omitted.

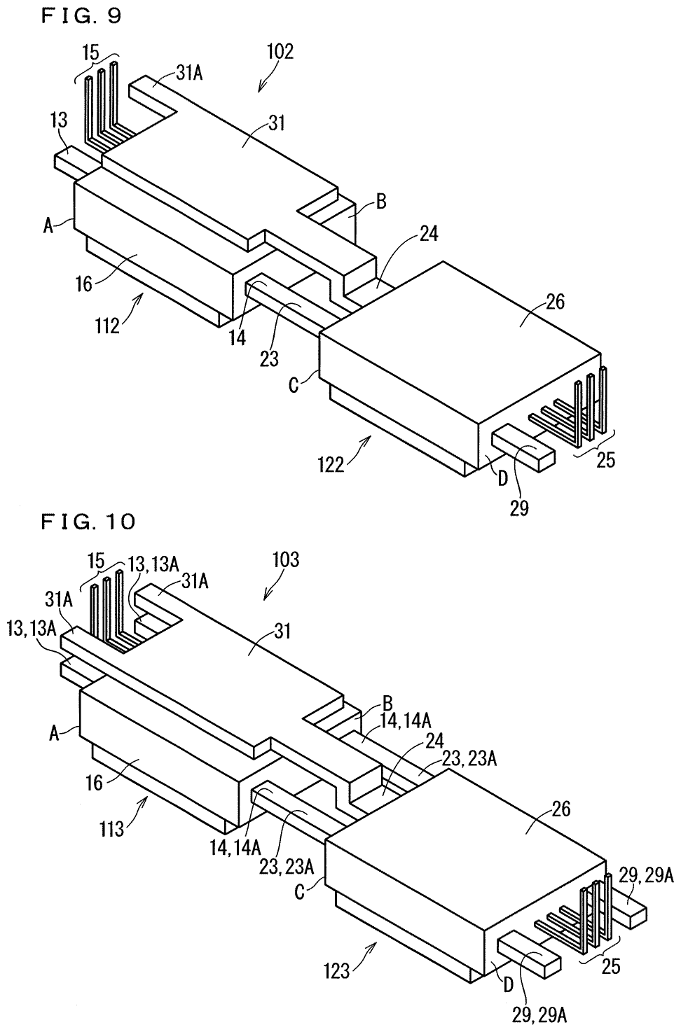

FIG. 9 is a view illustrating a configuration of a semiconductor device 102 according to the second embodiment. The semiconductor device 102 includes a third AC terminal 29 in a lower arm semiconductor package 122. An upper arm semiconductor package 112 is the same as the upper arm semiconductor package 111 of the first embodiment.

The third AC terminal 29 is formed of, for example, a metal frame. Although the illustration of the internal structure of the lower arm semiconductor package 122 is omitted, one end of the third AC terminal 29 is connected to the metal pattern 27 by a bonding material. That is, the third AC terminal 29 is electrically connected to the first pole side of the second semiconductor chip 22 via the metal pattern 27. The first pole side is a collector side of the IGBT. The other end of the third AC terminal 29 protrudes from the fourth side surface D of the lower arm semiconductor package 122. That is, the third AC terminal 29 is provided on the fourth side surface D as an example of a fourth surface different from the third side surface C on which the second AC terminal 23 is provided. The third AC terminal 29 has the same potential as the second AC terminal 23.

In such a semiconductor device 102, since the AC wiring for supplying power to the load can be connected between the first side surface A and the third side surface C or on the fourth side surface D side, the AC wiring can be easily taken out.

### Third Embodiment

A third embodiment is a subordinate concept of the first embodiment. In the third embodiment, components similar to those in the first or second embodiment are denoted by the same reference numerals, and the detailed description thereof will be omitted.

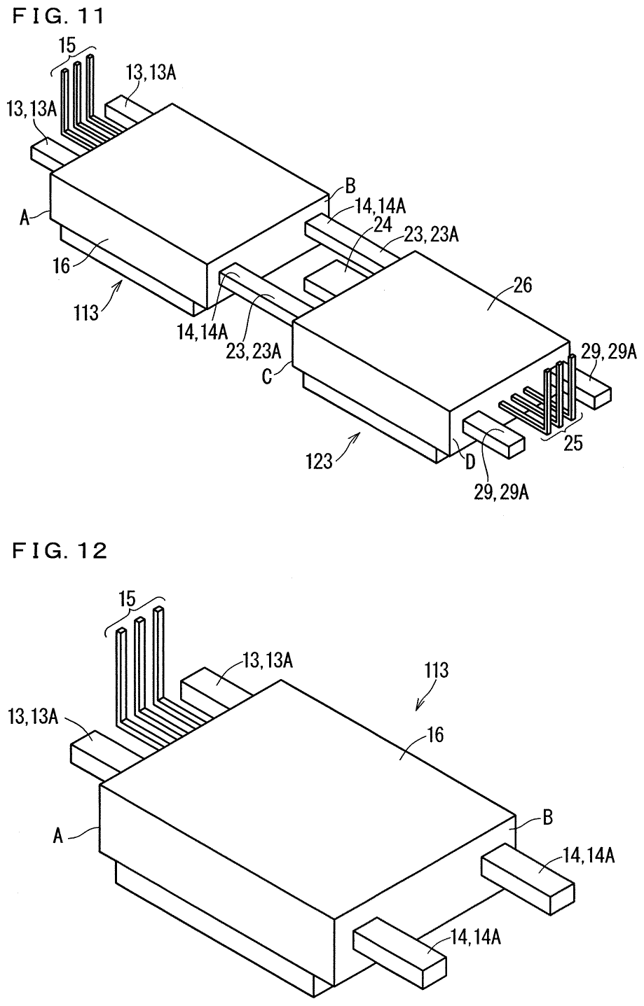

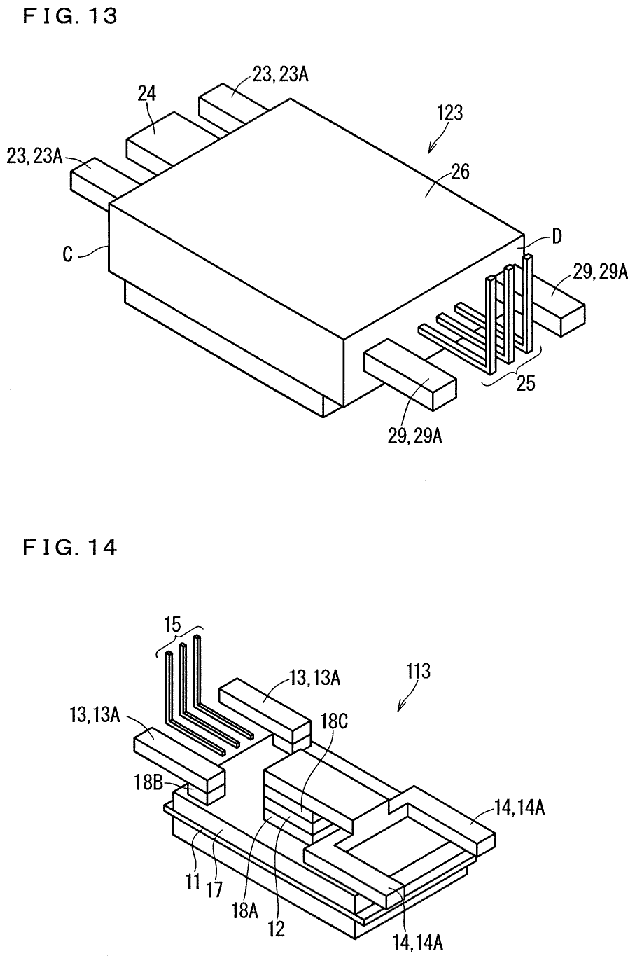

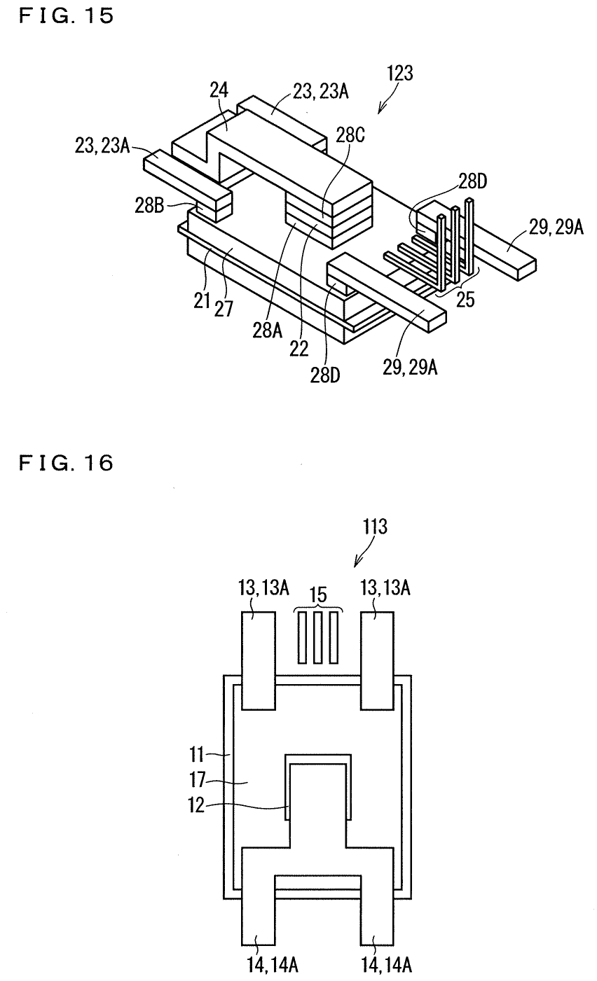

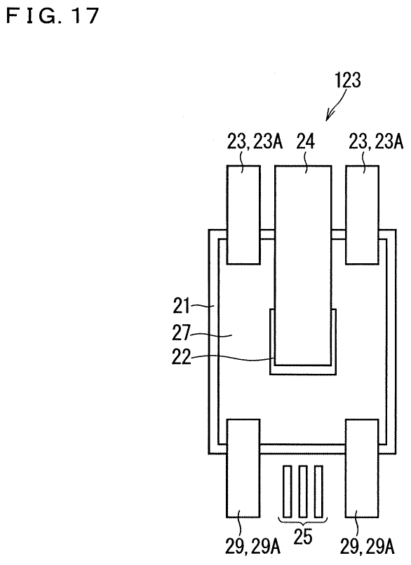

FIG. 10 is a view illustrating a configuration of a semiconductor device 103 according to the third embodiment. FIG. 11 is a view illustrating a connection configuration between an upper arm semiconductor package 113 and a lower arm semiconductor package 123. FIG. 12 is a view illustrating a configuration of the upper arm semiconductor package 113. FIG. 13 is a view illustrating a configuration of the lower arm semiconductor package 123. FIG. 14 is a view illustrating an internal structure of the upper arm semiconductor package 113. FIG. 15 is a view illustrating an internal structure of the lower arm semiconductor package 123. FIG. 16 is a plan view illustrating the internal structure of the upper arm semiconductor package 113. FIG. 17 is a plan view illustrating the internal structure of the lower arm semiconductor package 123.

The P terminal 13 includes two P terminal elements 13A. The two P terminal elements 13A are separate members, each formed of a metal frame. The P terminal element 13A is connected to the metal pattern 17 via a bonding material 18B. The two P terminal elements 13A protrude from two respective positions on the first side surface A of the upper arm semiconductor package 113. The two P terminal elements 13A are arranged on both sides of the control terminal 15.

As in the first embodiment, the first AC terminal 14 is electrically connected to the second pole side of the first semiconductor chip 12 by the bonding material 18C. The first AC terminal 14 according to the third embodiment includes two first AC terminal portions 14A that branch inside the upper arm semiconductor package 113 and protrude from two positions on the second side surface B.

The second AC terminal 23 includes two second AC terminal elements 23A. The two second AC terminal elements 23A are separate members, each formed of a metal frame. The second AC terminal element 23A is connected to the metal pattern 27 via a bonding material 28B. The two second AC terminal elements 23A protrude from two respective positions on the third side surface C of the lower arm semiconductor package 123. The two second AC terminal elements 23A are arranged on opposite sides of the N terminal 24. The second AC terminal element 23A is connected to the first AC terminal portion 14A.

The third AC terminal 29 includes two third AC terminal elements 29A. The two third AC terminal elements 29A are separate members, each formed of a metal frame. The third AC terminal element 29A is connected to the metal pattern 27 via a bonding material 28D. The two third AC terminal elements 29A protrude from two respective positions on the fourth side surface D of the lower arm semiconductor package 123. The two third AC terminal elements 29A are arranged on both sides of the control terminal 25.

The bus bar 31 includes two bus bar terminal portions 31A on the first side surface A side of the upper arm semiconductor package 113.

In such a semiconductor device 103, since the number of terminals increases, the current path also increases. Furthermore, since the current paths intersect, inductance is reduced.

The P terminal 13 may include three or more P terminal elements 13A. The first AC terminal 14 may include three or more first AC terminal portions 14A. The second AC terminal 23 may include three or more second AC terminal elements 23A. The third AC terminal 29 may include three or more third AC terminal elements 29A. In any case, effects similar to those described above are obtained.

### Fourth Embodiment

A fourth embodiment is a subordinate concept of the first embodiment. In the fourth embodiment, components similar to those in any one of the first to third embodiments are denoted by the same reference numerals, and detailed description thereof will be omitted.

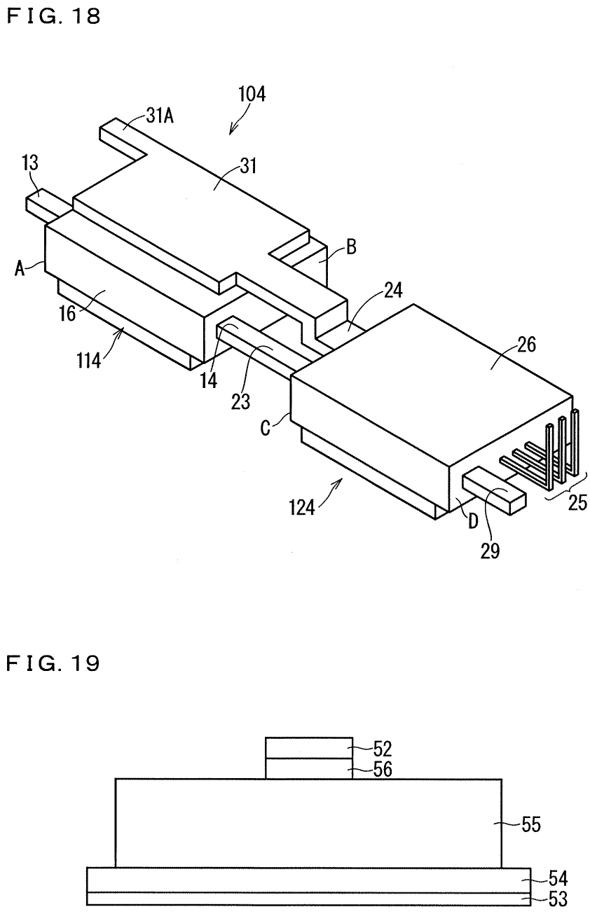

FIG. 18 is a view illustrating a configuration of a semiconductor device 104 according to the fourth embodiment. The semiconductor device 104 includes an upper arm semiconductor package 114 and a lower arm semiconductor package 124. The lower arm semiconductor package 124 is the same as the lower arm semiconductor package 122 of the second embodiment.

The upper arm semiconductor package 114 is not provided with the control terminal 15. In a case where it is not necessary to control a diode (not illustrated) or the like related to driving of the switching element 10, the control terminal 15 is not necessarily required.

Such a semiconductor device 104 increases the degree of freedom of layout when constructing a power control apparatus such as an inverter circuit.

Although the control terminal 25 is provided in the lower arm semiconductor package 124, the control terminal 25 need not be provided in a case where control of a diode or the like is not necessary. Similarly, the control terminals 15 and 25 need not be provided in both the upper arm semiconductor package 114 and the lower arm semiconductor package 124. In any case, effects similar to those described above are obtained.

### Fifth Embodiment

In a fifth embodiment, components similar to those in any of the first to fourth embodiments are denoted by the same reference numerals, and detailed description thereof will be omitted.

FIG. 19 is a side view illustrating an example of a holding structure of a semiconductor chip 52 according to the fifth embodiment. The semiconductor chip 52 corresponds to the first semiconductor chip 12 or the second semiconductor chip 22.

A semiconductor device according to the fifth embodiment includes a metal plate 53, an insulating material 54, and a heat spreader 55 instead of the insulating substrates 11 and 21 having the metal patterns 17 and 27.

The insulating material 54 is provided on the surface of the metal plate 53. The heat spreader 55 is provided on the insulating material 54. The heat spreader 55 holds the semiconductor chip 52 via a bonding material 56.

The heat spreader 55 has a larger heat capacity than the insulating substrates 11 and 21 having the metal patterns 17 and 27. Thus, such a semiconductor device reduces transient thermal resistance.

### Sixth Embodiment

A sixth embodiment is a subordinate concept of the first embodiment. In the sixth embodiment, components similar to those in any of the first to fifth embodiments are denoted by the same reference numerals, and detailed description thereof will be omitted.

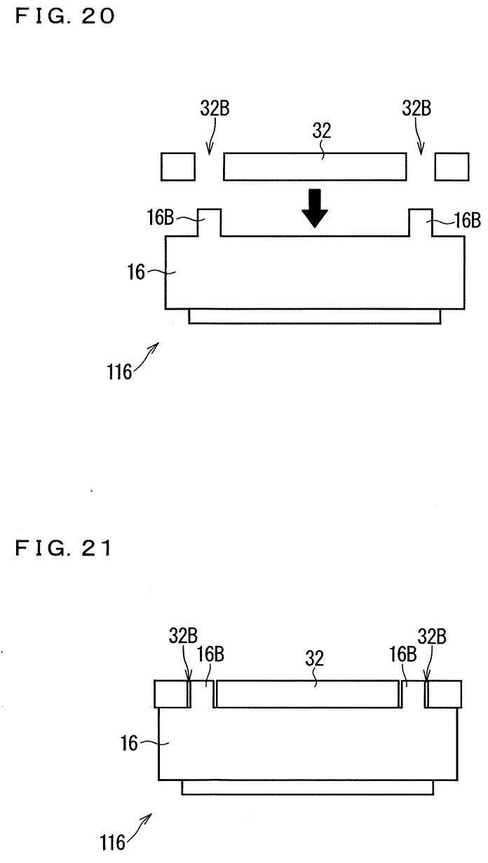

FIGS. 20 and 21 are views illustrating an example of a configuration of an upper arm semiconductor package 116 and a bus bar 32 according to the sixth embodiment.

The upper arm semiconductor package 116 includes two protrusions 16B on its upper surface. The protrusions 16B are each formed as a part of the sealing material 16. The bus bar 32 includes two holes 32B corresponding to the two protrusions 16B. The holes 32B of the bus bar 32 are fitted to the protrusions 16B of the upper arm semiconductor package 116.

In the assembly process of the semiconductor device, the mounting position of the bus bar 32 with respect to the position of the upper arm semiconductor package 116 is determined by the fitting structure. The number of each of the protrusions 16B and the holes 32B is not limited to two, and may be one or three or more.

### Seventh Embodiment

A seventh embodiment is a subordinate concept of the first embodiment. In the seventh embodiment, components similar to those in any one of the first to sixth embodiments are denoted by the same reference numerals, and a detailed description thereof is omitted.

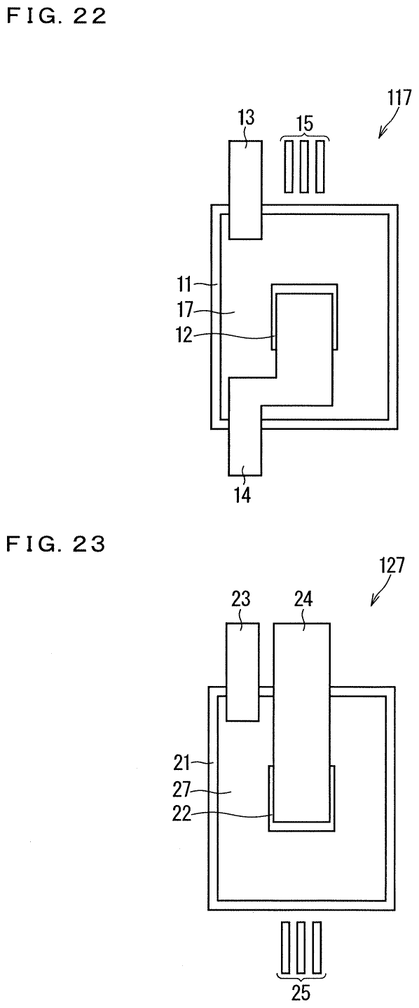

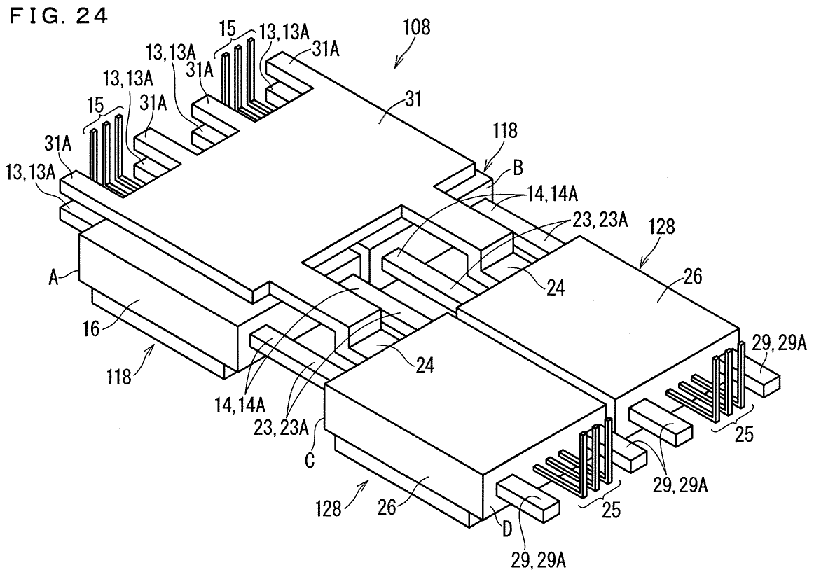

FIG. 22 is a plan view illustrating an internal structure of an upper arm semiconductor package 117 according to the seventh embodiment. FIG. 23 is a plan view illustrating an internal structure of a lower arm semiconductor package 127.

The first semiconductor chip 12 and the second semiconductor chip 22 include SiC as a semiconductor material. With such a configuration, the output of the semiconductor device increases.

### Eighth Embodiment

In an eighth embodiment, components similar to those in any of the first to seventh embodiments are denoted by the same reference numerals, and detailed description thereof will be omitted.

FIG. 24 is a view illustrating a configuration of a semiconductor device 108 according to an eighth embodiment.

The semiconductor device 108 includes two upper arm semiconductor packages 118 and two lower arm semiconductor packages 128. The two upper arm semiconductor packages 118 are arranged in parallel with each other. The two lower arm semiconductor packages 128 are arranged in parallel with each other. The upper arm semiconductor packages 118 each have the same configuration as the upper arm semiconductor package 113 according to the third embodiment. The lower arm semiconductor packages 128 each have the same configuration as the lower arm semiconductor package 123 according to the third embodiment.

The upper arm semiconductor packages 118 are each disposed so that the second side surface B thereof faces the third side surface C of the lower arm semiconductor package 128. The first AC terminal portion 14A is connected to the second AC terminal element 23A. Thus, the switching element 10 of the upper arm semiconductor package 118 and the switching element 10 of the lower arm semiconductor package 128 are connected in series with each other.

The bus bar 31 is one component, and is connected to all the N terminals 24 of the two lower arm semiconductor packages 128.

With such a configuration, since the area of the current path in the bus bar 31 is increased, the inductance is reduced.

Each of the two upper arm semiconductor packages 118 may have the same configuration as the upper arm semiconductor package according to any one of the first to seventh embodiments. Each of the two lower arm semiconductor packages 128 may have the same configuration as the lower arm semiconductor package according to any one of the first to seventh embodiments.

The number of each of the upper arm semiconductor packages 118 and the lower arm semiconductor packages 128 may be three. Even in this case, the bus bar 31 is one component, and is connected to all the N terminals 24.

### Ninth Embodiment

In a ninth embodiment, components similar to those in any one of the first to eighth embodiments are denoted by the same reference numerals, and a detailed description thereof is omitted.

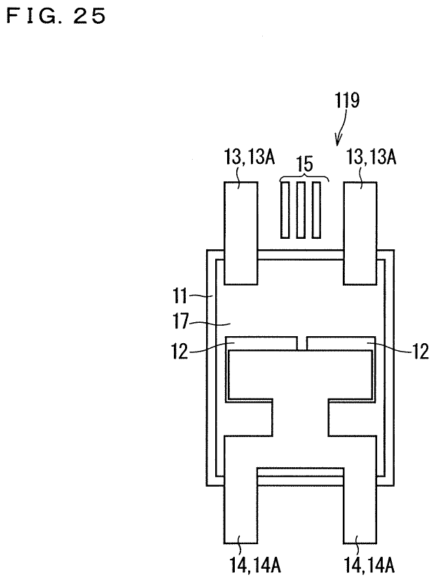

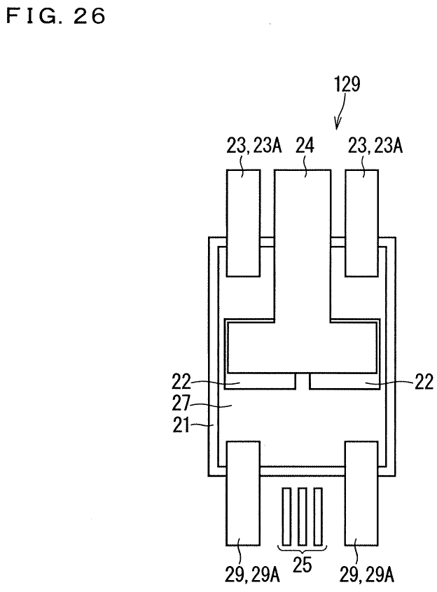

FIG. 25 is a plan view illustrating an internal structure of an upper arm semiconductor package 119 according to the ninth embodiment. FIG. 26 is a plan view illustrating an internal structure of a lower arm semiconductor package 129.

The upper arm semiconductor package 119 includes two first semiconductor chips 12. The first AC terminal 14 is collectively connected to the second pole side of the two first semiconductor chips 12. The second pole side is, for example, an emitter side of the IGBT.

The lower arm semiconductor package 129 includes two second semiconductor chips 22. The N terminal 24 is collectively connected to the second pole side of the two second semiconductor chips 22.

Since the plurality of first semiconductor chips 12 and the plurality of second semiconductors are mounted, the output of the semiconductor device increases.

In the ninth embodiment, the upper arm semiconductor package 119 may have the same configuration as the upper arm semiconductor package according to any one of Embodiments 1 to 7. The lower arm semiconductor package 129 may have the same configuration as the lower arm semiconductor package according to any one of the first to seventh embodiments.

Each of the number of first semiconductor chips 12 and the number of second semiconductor chips 22 may be three or more.

Although this disclosure has been described in detail, the above description is illustrative and not restrictive in all aspects. It is understood that numerous modifications not illustrated can be assumed.

In the present disclosure, the embodiments can be freely combined, and the embodiments can be appropriately modified or omitted.

### EXPLANATION OF REFERENCE SIGNS

10 switching element, 11 insulating substrate, 12 first semiconductor chip, 13 P terminal, 13A P terminal element, 14 first AC terminal, 14A first AC terminal portion, 15 control terminal, 16 sealing material, 16B protrusion, 17 metal pattern, 18A to 18C bonding material, 19 control wire, 21 insulating substrate, 22 second semiconductor chip, 23 second AC terminal, 23A second AC terminal element, 24 N terminal, 25 control terminal, 26 sealing material, 27 metal pattern, 28A to 28D bonding material, 29 third AC terminal, 29A third AC terminal element, 31 bus bar, 31A bus bar terminal portion, 32 bus bar, 32B hole, 52 semiconductor chip, 53 metal plate, 54 insulating material, 55 heat spreader, 56 bonding material, 101 to 104 semiconductor device, 108 semiconductor device, 111 to 114 upper arm semiconductor package, 116 to 119 upper arm semiconductor package, 121 to 124 lower arm semiconductor package, 127 to 129 lower arm semiconductor package, A first side surface, B second side surface, C third side surface, D fourth side surface.

1. A semiconductor device comprising:
a first semiconductor package including a first semiconductor chip;
a first terminal provided on a first surface of the first semiconductor package and electrically connected to a first pole side of the first semiconductor chip;
a first output terminal provided on a second surface of the first semiconductor package and electrically connected to a second pole side of the first semiconductor chip;
a second semiconductor package including a second semiconductor chip;
a second output terminal provided on a third surface of the second semiconductor package and electrically connected to the first pole side of the second semiconductor chip;
a second terminal provided on the third surface of the second semiconductor package and electrically connected to the second pole side of the second semiconductor chip; and
a bus bar connected to the second terminal, wherein
the first output terminal is connected to the second output terminal, and
the bus bar extends from the second terminal in a direction of the first surface on which the first terminal is provided.

2. The semiconductor device according to claim 1, wherein the first semiconductor package is disposed so that the second surface of the first semiconductor package faces the third surface of the second semiconductor package,
the bus bar includes at least one bus bar terminal portion on the first surface side of the first semiconductor package and is provided on an upper surface of the first semiconductor package, and
the at least one bus bar terminal portion is disposed side by side with the first terminal on the first surface side of the first semiconductor package.

3. The semiconductor device according to claim 1, further comprising a third output terminal provided on a fourth surface of the second semiconductor package and electrically connected to the first pole side of the second semiconductor chip.

4. The semiconductor device according to claim 2, wherein:
the first terminal includes a plurality of terminal elements each protruding from a plurality of positions on the first surface of the first semiconductor package;
the first output terminal includes a plurality of output terminal portions each branching inside the first semiconductor package and protruding from a plurality of positions on the second surface;
the second output terminal includes a plurality of output terminal elements each protruding from a plurality of positions on the third surface of the second semiconductor package; and
the at least one bus bar terminal portion is a plurality of bus bar terminal portions.

5. The semiconductor device according to claim 1, further comprising a control terminal for transmitting a control signal related to control of a switching element included in the first semiconductor chip or the second semiconductor chip.

6. The semiconductor device according to claim 1, further comprising an insulating substrate including a metal pattern on a surface, wherein
the insulating substrate holds the first semiconductor chip or the second semiconductor chip via the metal pattern.

7. The semiconductor device according to claim 1, further comprising:
a metal plate;
an insulating material provided on a surface of the metal plate; and
a heat spreader provided on the insulating material, wherein
the heat spreader holds the first semiconductor chip or the second semiconductor chip.

8. The semiconductor device according to claim 2, wherein the first semiconductor package includes at least one protrusion on the upper surface,
the bus bar includes at least one hole, and
the at least one hole of the bus bar is fitted to the at least one protrusion of the first semiconductor package.

9. The semiconductor device according to claim 1, wherein the first semiconductor chip or the second semiconductor chip contains SiC as a semiconductor material.

10. A semiconductor device comprising:
a plurality of first semiconductor packages arranged in parallel with each other and each including a first semiconductor chip;
a first terminal provided on a first surface of each of the plurality of first semiconductor packages and electrically connected to a first pole side of the first semiconductor chip;
a first output terminal provided on a second surface of each of the plurality of first semiconductor packages and electrically connected to a second pole side of the first semiconductor chip;
a plurality of second semiconductor packages arranged in parallel with each other and each including a second semiconductor chip;
a second output terminal provided on a third surface of each of the plurality of second semiconductor packages and electrically connected to the first pole side of the second semiconductor chip;
a second terminal provided on the third surface of each of the plurality of second semiconductor packages and electrically connected to the second pole side of the second semiconductor chip; and
a bus bar connected to the second terminal, wherein
the first output terminal is connected to the second output terminal, and
the bus bar extends from the second terminal in a direction of the first surface on which the first terminal is provided.

11. A semiconductor device comprising:
a first semiconductor package including a plurality of first semiconductor chips;
a first terminal provided on a first surface of the first semiconductor package and electrically connected to a first pole side of the plurality of first semiconductor chips;
a first output terminal provided on a second surface of the first semiconductor package and electrically connected to a second pole side of the plurality of first semiconductor chips;
a second semiconductor package including a plurality of second semiconductor chips;
a second output terminal provided on a third surface of the second semiconductor package and electrically connected to the first pole side of the plurality of second semiconductor chips;
a second terminal provided on the third surface of the second semiconductor package and electrically connected to the second pole side of the plurality of second semiconductor chips; and
a bus bar connected to the second terminal, wherein
the first output terminal is connected to the second output terminal, and
the bus bar extends from the second terminal in a direction of the first surface on which the first terminal is provided.
